(19) United States
(12) Patent Application Publication
(10) Pub. No.: US 2024/0282744 A1
(43) Pub. Date: Aug. 22, 2024

(54) SEMICONDUCTOR DEVICE

(71) Applicant: FUJI ELECTRIC CO., LTD., Kawasaki-shi (JP)

(72) Inventor: Takafumi YAMADA, Matsumoto-city (JP)

(73) Assignee: FUJI ELECTRIC CO., LTD., Kawasaki-shi (JP)

(21) Appl. No.: 18/397,756

(22) Filed: Dec. 27, 2023

(30) Foreign Application Priority Data
Feb. 17, 2023 (JP) 2023-023138

(51) Int. Cl. H01L 23/00

(52) U.S. Cl. CPC H01L 24/40; H01L 24/37; H01L 23/49838; H01L 24/29; H01L 24/32; H01L 24/45; H01L 24/48; H01L 24/49; H01L 24/73; H01L 25/072; H01L 2224/05553; H01L 2224/0603; H01L 2224/29109; H01L 2224/29111; H01L 2224/29113; H01L 2224/29117; H01L 2224/29118; H01L 2224/2912; H01L 2224/29123; H01L 2224/29124; H01L 2224/29138; H01L 2224/29139; H01L 2224/29147; H01L 2224/29155; H01L 2224/29157; H01L 2224/29166; H01L 2224/2917; H01L 2224/32227; H01L 2224/3701; H01L 2224/37124; H01L 2224/37147; H01L 2224/37655; H01L 2224/37663; H01L 2224/40106; H01L 2224/40227; H01L 2224/40499; H01L 2224/45124; H01L 2224/45147; H01L 2224/48227; H01L 2224/49175; H01L 2224/73221; H01L 2224/73263; H01L 2224/73265; H01L 2924/01005; H01L 2924/01012; H01L 2924/01013; H01L 2924/01014; H01L 2924/01022; H01L 2924/01027; H01L 2924/01028; H01L 2924/01029; H01L 2924/0103; H01L 2924/01032; H01L 2924/0104; H01L 2924/01047; H01L 2924/01049; H01L 2924/0105; H01L 2924/01051; H01L 2924/01083; H01L 2924/0132; H01L 2924/10253; H01L 2924/10272; H01L 2924/12031; H01L 2924/12032; H01L 2924/13055; H01L 2924/13091

(57) ABSTRACT

A semiconductor device includes a semiconductor chip including an upper electrode, a lead frame having a bonding part and a rising part, and a bonding member joining the upper electrode to the bonding part. The upper electrode has electrode lateral surfaces including a first lateral surface. The bonding part has a bonding front surface and terminal lateral surfaces that include a second lateral surface. The bonding part is joined to the upper electrode such that the second lateral surface faces the first lateral surface. The rising part extends upward from the first lateral surface. In a direction parallel to the electrode front surface, a first shortest distance between a center of the electrode front surface in a plan view and the second lateral surface is equal to or greater than 40% of a second shortest distance between the first lateral surface and the second lateral surface.

### CROSS-REFERENCE TO RELATED APPLICATION

This application is based upon and claims the benefit of priority of the prior Japanese Patent Application No. 2023-023138, filed on Feb. 17, 2023, the entire contents of which are incorporated herein by reference.

### BACKGROUND OF THE INVENTION

### 1. Field of the Invention

The embodiments discussed herein relate to a semiconductor device.

### 2. Background of the Related Art

A connector includes an electrode bonding part joined to a gate electrode of a semiconductor chip via solder; a first connecting part rising from one end of the electrode bonding part; a substrate bonding part joined to a wiring pattern via solder; and a second connecting part rising from one end of the substrate bonding part. Bonding surfaces of the electrode bonding part and the substrate bonding part of the connector are inclined against bonded surfaces of the gate electrode and the wiring pattern (see, for example, International Publication Pamphlet No. WO 2015/059882). An upper wiring spanning the gap between a semiconductor chip and a substrate electrode to join them includes rising portions that rise from individual bonding parts of the upper wiring. The rising portions rise at an angle (see, for example, International Publication Pamphlet No. WO 2017/183580). A metal wiring board electrically connected to an upper electrode of a semiconductor element includes a bonding part connected to the upper electrode; and a rising part connected to a first end of the bonding part and extending in a direction away from the upper surface of the semiconductor element (see, for example, Japanese Laid-open Patent Publication No. 2018-098283).

A conductive plate which has a plating region formed in a desired region is joined to a semiconductor element by soldering, and thereby the solder and the semiconductor element form an obtuse angle (see, for example, Japanese Laid-open Patent Publication No. 2003-332393). A power module includes a graphite with plate anisotropic thermal conductivity, a first end of which is connected to the front surface of a semiconductor chip and a second end of which is connected to an insulating substrate (see, for example, Japanese Laid-open Patent Publication No. 2019-071399).

### SUMMARY OF THE INVENTION

According to an aspect, there is provided a semiconductor device including a semiconductor chip including at a chip front surface thereof, an upper electrode having an electrode front surface and electrode lateral surfaces that surround an outer periphery of the upper electrode in a plan view of the semiconductor device, the electrode lateral surfaces including a first lateral surface; a lead frame having a bonding part and a rising part, the bonding part having a bonding front surface and terminal lateral surfaces that surround an outer periphery of the bonding part in the plan view, the terminal lateral surfaces including a second lateral surface, the bonding part being joined to the electrode front surface of the upper electrode such that the second lateral surface faces the first lateral surface, the rising part extending upward with respect to the electrode front surface from the second lateral surface; and a bonding member joining the upper electrode to the bonding part, wherein in a direction parallel to the electrode front surface, a first shortest distance between a center of the electrode front surface in the plan view and the second lateral surface is equal to or greater than 40% of a second shortest distance between the first lateral surface and the second lateral surface.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device of a first embodiment;

FIG. 2 is a lateral view of the semiconductor device of the first embodiment;

FIG. 3 is a cross-sectional view of the semiconductor device of the first embodiment;

FIG. 4 is a rear view of the semiconductor device of the first embodiment;

FIG. 5 is a plan view of a semiconductor unit included in the semiconductor device of the first embodiment;

FIG. 6 is a cross-sectional view of the semiconductor unit included in the semiconductor device of the first embodiment;

FIGS. 7A and 7B illustrate bonding of a lead frame to a semiconductor chip according to a reference example;

FIGS. 8A and 8B illustrate an output electrode of a different semiconductor chip included in the semiconductor device of the first embodiment;

FIGS. 9A and 9B each illustrate a lead frame joined to the different semiconductor chip included in the semiconductor device of the first embodiment;

FIGS. 10A and 10B are graphs illustrating temperature and distortion, respectively, in relation to a distance from a center of the output electrode of the different semiconductor chip included in the semiconductor device of the first embodiment;

FIG. 11 is a cross-sectional view of a semiconductor unit included in a semiconductor device of a second embodiment; and

FIG. 12 is a cross-sectional view of a semiconductor unit included in a semiconductor device of a third embodiment.

### DETAILED DESCRIPTION OF THE INVENTION

Several embodiments will be described below with reference to the accompanying drawings. Note that in the following the terms “front surface” and “top face” refer to the X-Y plane facing upward (the +Z direction) in a semiconductor device 1 of the drawings. Similarly, the term “upper” refers to the upward direction (the +Z direction) of the illustrated semiconductor device 1. On the other hand, the terms “rear surface” and “bottom face” refer to the X-Y plane facing downward (the −Z direction) in the illustrated semiconductor device 1. Similarly, the term “lower” refers to the downward direction (the −Z direction) of the illustrated semiconductor device 1. These terms have the same orientational relationships in other drawings if needed. “High” in position refers to an upper position (the +Z direction) in the illustrated semiconductor device 1. On the other hand, “low” in position refers to a lower position (the −Z direction) in the illustrated semiconductor device 1. The terms “front surface”, “top face”, and “upper”; the terms “rear surface”, “bottom face”, and “lower”; and the term “lateral surface” are simply expedient expressions used to specify relative positional relationships, and are not intended to limit the technical ideas of the embodiments described herein. For example, the terms “upper” and “lower” do not necessarily imply the vertical direction to the ground surface. That is, the “upper” and “lower” directions are not defined in relation to the direction of the gravitational force. In addition, the term “major component” in the following refers to a constituent having a concentration equal to 80 vol % or higher. The phrase “substantially the same” refers to where two or more things being compared have a difference of no more than ±10%. In addition, the terms “perpendicular”, “orthogonal”, and “parallel” may also include substantially perpendicular, substantially orthogonal, and substantially parallel, as appropriate, which may include a margin of error of ±10° or less.

### (a) First Embodiment

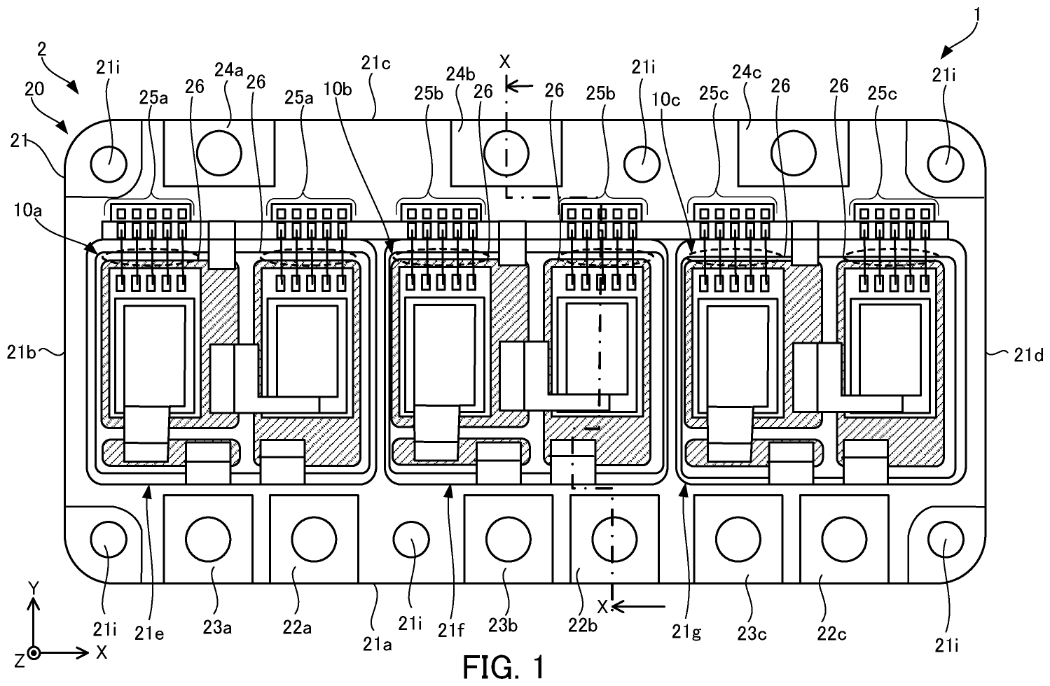

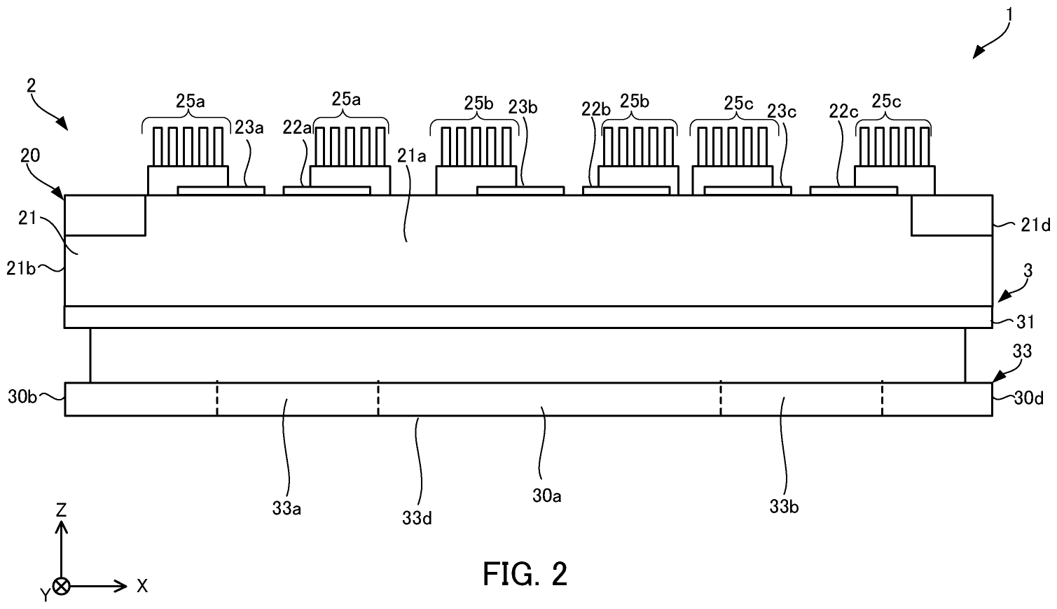

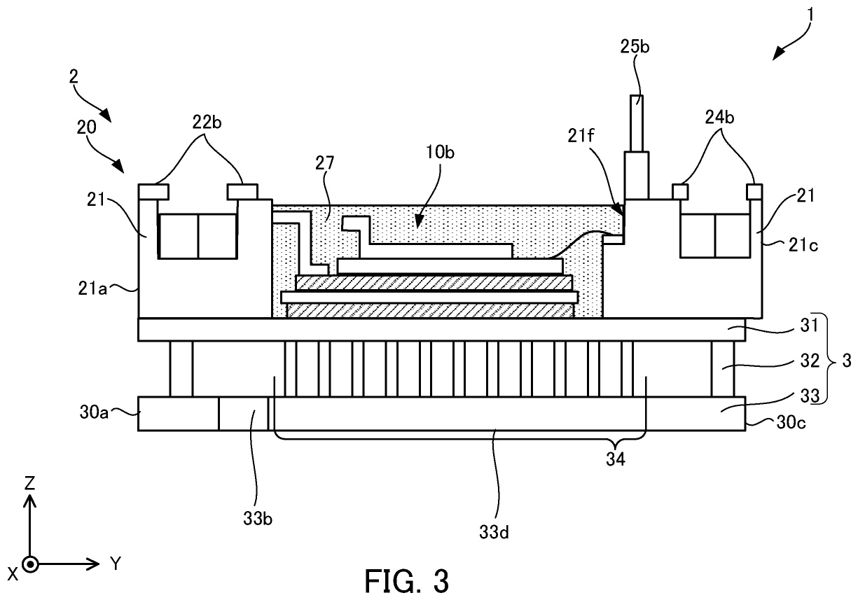

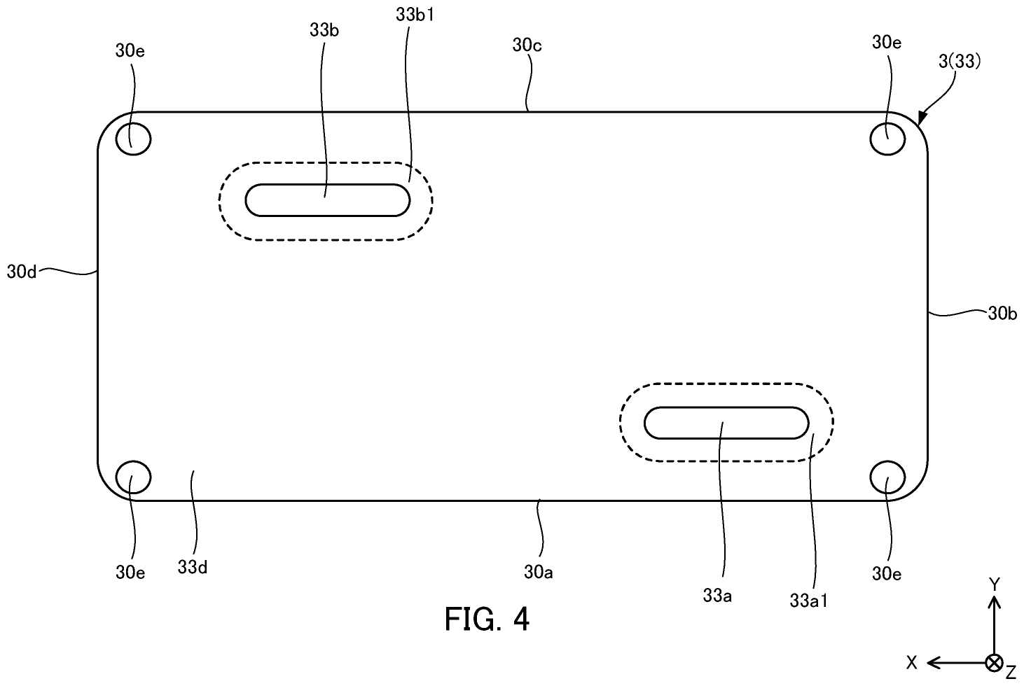

Next described is the semiconductor device 1 according to a first embodiment, with reference to FIGS. 1 to 4. FIG. 1 is a plan view of the semiconductor device of the first embodiment. FIG. 2 is a lateral view of the semiconductor device of the first embodiment. FIG. 3 is a cross-sectional view of the semiconductor device of the first embodiment. FIG. 4 is a rear view of the semiconductor device of the first embodiment. Note that FIG. 1 omits the illustration of a sealing member 27. The lateral view of FIG. 2 is a cut through the X-Z plane of FIG. 1, viewed in the direction of the Y-axis. The cross-sectional view of FIG. 3 is taken along dashed-dotted line X-X of FIG. 1. The rear view of FIG. 4 is obtained by rotating the semiconductor device 1 of FIG. 1 around a center line passing through the centers of sidewalls 21a and 21c.

The semiconductor device 1 includes a semiconductor module 2 and a cooling device 3. The semiconductor module 2 includes semiconductor units 10a, 10b, and 10c and a case 20 for housing the semiconductor units 10a, 10b, and 10c. The semiconductor units 10a, 10b, and 10c are arranged in a line on the cooling device 3. The case 20 is installed on the cooling device 3 such that the semiconductor units 10a, 10b, and 10c are housed in the case 20. The semiconductor units 10a, 10b, and 10c housed in the case 20 are sealed with the sealing member 27. Note that the semiconductor units 10a, 10b, and 10c all have the same configuration. The semiconductor units 10a, 10b, and 10c will simply be called “semiconductor units 10” if there is no need to distinguish between them. Details of the semiconductor units 10 will be described later.

The case 20 includes an outer frame 21; first connection terminals 22a, 22b, and 22c; second connection terminals 23a, 23b, and 23c; a U-phase output terminal 24a; a V-phase output terminal 24b; a W-phase output terminal 24c; and control terminals 25a, 25b, and 25c.

The outer frame 21 has a rectangular shape in plan view and is surrounded on all four sides by the sidewalls 21a, 21b, 21c, and 21d. Note that the sidewalls 21a and 21c are the long sides of the outer frame 21 while the sidewalls 21b and 21d are the short sides of the outer frame 21. The corners where two adjacent sidewalls 21a, 21b, 21c, and 21d meet do not necessarily have a right angle in plan view. Each of the corners may be R-chamfered, for example, as illustrated in FIG. 1. The rear surface of the outer frame 21 (the sidewalls 21a, 21b, 21c, and 21d) may lie in the same plane and be parallel to the X-Y plane.

At each corner of the front surface of the outer frame 21, a mounting hole 21i is formed through the outer frame 21. Note that the mounting holes 21i may be formed below the front surface of the outer frame 21. Furthermore, yet another mounting hole 21i penetrating the outer frame 21 may be formed on each of the sidewall 21a and 21c sides of the outer frame 21.

The outer frame 21 includes unit housing parts 21e, 21f, and 21g positioned at the center of the front surface in the ±Y direction along the sidewalls 21a and 21c (the ±X direction). In plan view, each of the unit housing parts 21e, 21f, and 21g is open and demarcated in the shape of a rectangle on the front surface of the outer frame 21. The semiconductor units 10a, 10b, and 10c are housed in the unit housing parts 21e, 21f, and 21g, respectively. Therefore, the size of the unit housing parts 21e, 21f, and 21g may be such that the semiconductor units 10a, 10b, and 10c are storable therein.

In plan view, the outer frame 21 has, on the sidewall 21a side of the front surface, the first connection terminals 22a, 22b, and 22c and the second connection terminals 23a, 23b, and 23c aligned along the sidewall 21a (the ±X direction). The first connection terminals 22a, 22b, and 22c may be positive input terminals (P terminals). The second connection terminals 23a, 23b, and 23c may be negative input terminals (N terminals).

In addition, the outer frame 21 has, on the sidewall 21c side of the front surface, the U-phase output terminal 24a, the V-phase output terminal 24b, and the W-phase output terminal 24c aligned along the sidewall 21c (the ±X direction). At this time, the U-phase output terminal 24a is located across the unit housing part 21e from the first connection terminal 22a and the second connection terminal 23a. Similarly, the V-phase output terminal 24b is located across the unit housing part 21f from the first connection terminal 22b and the second connection terminal 23b. The W-phase output terminal 24c is located across the unit housing part 21g from the first connection terminal 22c and the second connection terminal 23c.

Note that the front surface of the outer frame 21 houses nuts below (the −Z direction) the openings of the first connection terminals 22a, 22b, and 22c and the second connection terminals 23a, 23b, and 23c in such a manner as to oppose these openings. The front surface of the outer frame 21 also houses nuts below (the −Z direction) the openings of the U-phase output terminal 24a, the V-phase output terminal 24b, and the W-phase output terminal 24c in such a manner as to oppose these openings. Further, the control terminals 25a, 25b, and 25c are positioned on the front surface of the outer frame 21, in plan view, between the unit housing parts 21e, 21f, and 21g and the U-phase output terminal 24a, the V-phase output terminal 24b, and the W-phase output terminal 24c, respectively. Here, each set of the control terminals 25a, 25b, and 25c may be divided into two groups for the individual unit housing parts 21e, 21f, and 21g, as depicted in FIG. 1.

The aforementioned outer frame 21 including the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c is integrally formed by injection molding using a thermoplastic resin. In this manner, the case 20 is configured. As the thermoplastic resin, any of the following may be used: a poly phenylene sulfide resin; a polybutylene terephthalate resin; a polybutylene succinate resin; a polyamide resin; and an acrylonitrile butadiene styrene resin.

The first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c are made of a metal with excellent electrical conductivity. Such a metal is, for example, copper, aluminum, or an alloy containing at least one of these as a major component. Plating may be applied to coat the surfaces of the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c. In this case, a material used for plating is, for example, nickel, a nickel-phosphorus alloy, or a nickel-boron alloy. The plated first connection terminals 22a, 22b, and 22c, second connection terminals 23a, 23b, and 23c, U-phase output terminal 24a, V-phase output terminal 24b, W-phase output terminal 24c, and control terminals 25a, 25b, and 25c exhibit improved corrosion resistance. Note that, hereinafter, the first connection terminals 22a, 22b, and 22c will be referred to as the first connection terminals 22 unless otherwise distinguished. Similarly, the second connection terminals 23a, 23b, and 23c will be referred to as the second connection terminals 23, and the U-phase output terminal 24a, the V-phase output terminal 24b, and the W-phase output terminal 24c will be referred to as the output terminals 24.

The sealing member 27 may be a thermosetting resin. The thermosetting resin is, for example, epoxy resin, phenolic resin, maleimide resin, or polyester resin; however, epoxy resin is preferred. A filler may be added to the sealing member 27. The filler may be ceramics with insulation properties and high thermal conductivity.

The cooling device 3 includes an inlet 33a through which a refrigerant flows into the inside, and an outlet 33b through which the refrigerant having circulated inside flows out to the outside. The cooling device 3 cools the semiconductor units 10 by from discharging heat the semiconductor units 10 via the refrigerant. Examples of the refrigerant used here include water, an antifreeze solution (ethylene glycol aqueous solution), and a long-life coolant. The cooling device 3 may include a pump and a heat dissipation device (radiator). The pump makes the refrigerant circulate by causing it to flow into the inlet 33a of the cooling device 3 and again causing the refrigerant that has flowed out from the outlet 33b to flow back into the inlet 33a. The heat dissipation device receives the refrigerant flowing out from the cooling device 3 and externally radiates the heat of the refrigerant, to which the heat of the semiconductor units 10 has been conducted.

The above-described cooling device 3 includes a top plate 31, a sidewall 32 connected in a circular pattern to the rear surface of the top plate 31, and a cooling bottom plate 33 opposing the top plate 31 and connected to the rear surface of the sidewall 32. The top plate 31 has a rectangular shape, surrounded on the four sides by long sides and short sides in plan view, and has a fastener hole 30e in each of the four corners. Each corner of the top plate 31 may be R-chamfered in plan view. On the front surface of the top plate 31, the semiconductor units 10a, 10b, and 10c are bonded along the ±X direction. The sidewall 32 is formed continuously in a circular pattern on the rear surface of the top plate 31. Multiple heat dissipation fins 34 are provided, on the rear surface of the top plate 31, in a region corresponding to the region where the semiconductor units 10a, 10b, and 10c are disposed.

The cooling bottom plate 33 has a flat plate-like shape, and has the same shape as the top plate 31 in plan view. That is, the cooling bottom plate 33 has a rectangular shape surrounded on the four sides by long sides 30a and 30c and short sides 30b and 30d in plan view, and has, in the four corners, the fastener holes 30e corresponding to those of the top plate 31. In addition, each corner of the cooling bottom plate 33 may also be R-chamfered. The cooling bottom plate 33 has a front surface and a bottom surface 33d that are parallel to each other. The bottom surface 33d of the cooling bottom plate 33 is flat with no difference in level and lies in the same plane. Furthermore, the bottom surface 33d of the cooling bottom plate 33 and the front surface of the top plate 31 may also be parallel to each other. The bottom surface 33d of the cooling bottom plate 33 is provided with the inlet 33a and the outlet 33b through which the refrigerant flows in and out, respectively. Note that sealing areas 33a1 and 33b1 are provided around the inlet 33a and the outlet 33b on the bottom surface 33d of the cooling bottom plate 33, to surround the inlet 33a and the outlet 33b, respectively. Water distribution heads are attached to the inlet 33a and the outlet 33b via ring-shaped rubber packings in the sealing areas 33a1 and 33b1 surrounding the inlet 33a and the outlet 33b. A water distribution pipe connected to the pump is attached to the water distribution heads.

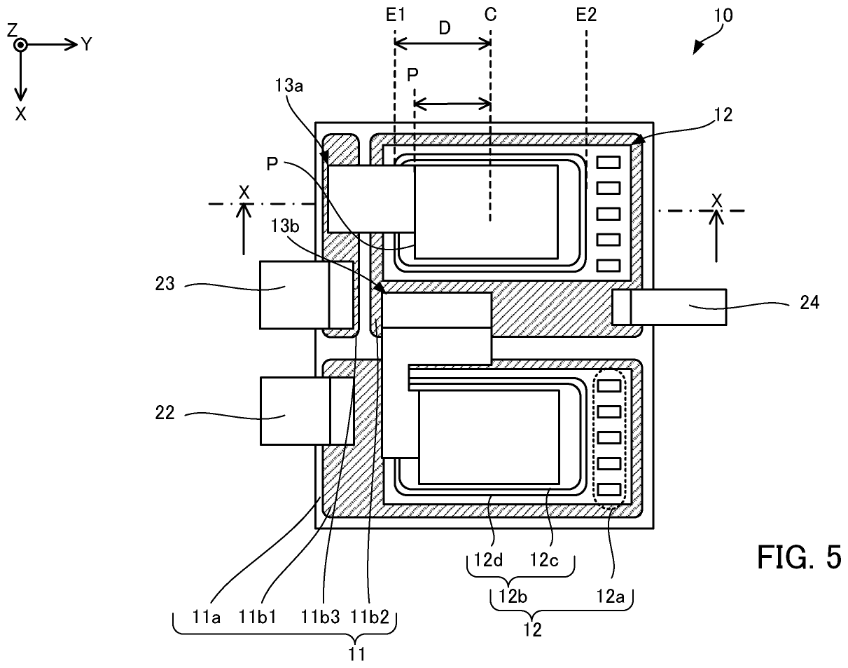

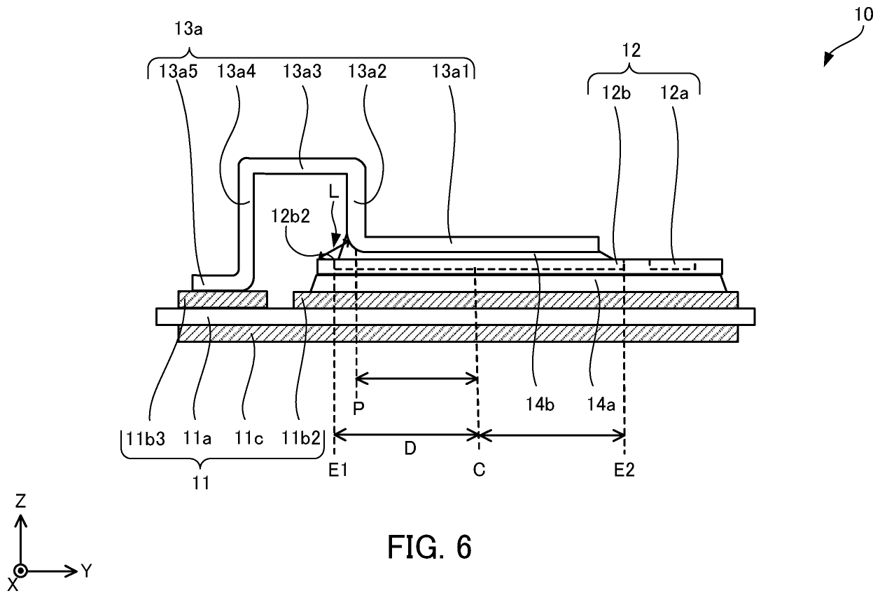

The semiconductor unit 10 is described next with reference to FIGS. 5 and 6. FIG. 5 is a plan view of a semiconductor unit included in the semiconductor device of the first embodiment. FIG. 6 is a cross-sectional view of the semiconductor unit included in the semiconductor device of the first embodiment. Note that FIG. 5 depicts a case where the first connection terminal 22, the second connection terminal 23, and the output terminal 24 included in the case 20 are connected to the semiconductor unit 10. The cross-sectional view of FIG. 6 is taken along dashed-dotted line X-X of FIG. 5.

The semiconductor unit 10 includes an isolated circuit board 11, semiconductor chips 12, and lead frames 13a and 13b. The semiconductor chips 12 are bonded to the isolated circuit board 11 via bonding members 14a. The lead frames 13a and 13b are bonded to the semiconductor chips 12 via bonding members 14b.

The isolated circuit board 11 includes an insulating plate 11a, wiring boards 11b1, 11b2, and 11b3, and a metal plate 11c. The insulating plate 11a and the metal plate 11c have a rectangular shape in plan view. In addition, the insulating plate 11a and the metal plate 11c may have R- or C-chamfered corners. The metal plate 11c is smaller in size than the insulating plate 11a in plan view, and is thus formed within the insulating plate 11a.

The insulating plate 11a is made of a material with insulation properties and excellent thermal conductivity. The insulating plates 11a may be made of ceramics or insulating resin. The ceramics here is, for example, aluminum oxide, aluminum nitride, or silicon nitride. The insulating resin here is, for example, paper phenol substrate, paper epoxy substrate, glass composite substrate, or glass epoxy substrate.

The wiring boards 11b1, 11b2, and 11b3 are formed on the front surface of the insulating plate 11a. The wiring boards 11b1, 11b2, and 11b3 are made of a metal with excellent electrical conductivity. The metal is, for example, copper, aluminum, or an alloy whose major component is at least one of these. Plating may be applied to coat the surfaces of the wiring boards 11b1, 11b2, and 11b3. In this case, a material used for plating is, for example, nickel, a nickel-phosphorus alloy, or a nickel-boron alloy. The plated wiring boards 11b1, 11b2, and 11b3 exhibit improved corrosion resistance.

The wiring board 11b1 occupies half the area of the front surface of the insulating plate 11a on the +X direction side, and spreads across the entire region from the −Y direction side to the +Y direction side. On the other hand, the wiring board 11b2 occupies half the area of the front surface of the insulating plate 11a on the −X direction side. The wiring board 11b2 extends from the +Y direction side to the −Y direction side, with a gap to the −Y direction side. The wiring board 11b3 occupies an area, on the front surface of the insulating plate 11a, surrounded by the wiring boards 11b1 and 11b2.

The above-described wiring boards 11b1, 11b2, and 11b3 are formed on the front surface of the insulating plate 11a by the following means. For example, a metal plate is formed on the front surface of the insulating plate 11a and then subjected to etching or the like, to thereby obtain the wiring boards 11b1, 11b2, and 11b3 with predetermined shapes. Alternatively, the wiring boards 11b1, 11b2, and 11b3 preliminarily cut out of a metal plate are pressure bonded to the front surface of the insulating plate 11a. Note that the wiring boards 11b1, 11b2, and 11b3 are merely examples, and appropriate changes may be made to the number of wiring boards 11b, their shapes, sizes and locations, as needed basis.

The metal plate 11c is formed on the rear surface of the insulating plate 11a. The metal plate 11c has a rectangular shape. The area of the metal plate 11c in plan view is smaller than that of the insulating plate 11a, but larger than the area of the region where the wiring boards 11b1, 11b2, and 11b3 are formed. The metal plate 11c may have R- or C-chamfered corners. The metal plate 11c is smaller in size than the insulating plate 11a, and is formed on the entire surface of the insulating plate 11a except for the edges. The metal plate 11c is made of a metal with excellent thermal conductivity as a major component. The metal is, for example, copper, aluminum, or an alloy including at least one of these. Plating may be applied to coat the surface of the metal plate 11c. In this case, a material used for plating is, for example, nickel, a nickel-phosphorus alloy, or a nickel-boron alloy. The plated metal plate 11c exhibits improved corrosion resistance.

As the isolated circuit board 11 having the above-described configuration, for example, a direct copper bonding (DCB) substrate, an active metal brazed (AMB) substrate, or a resin insulating substrate may be used. The isolated circuit board 11 may be attached to the front surface of the top plate 31 of the cooling device 3 via a bonding member (not illustrated). This allows heat generated in the semiconductor chip 12 to be conducted to the cooling device 3 via the wiring boards 11b1 and 11b2, the insulating plate 11a, and the metal plate 11c and then radiated outwards.

The bonding members 14a and 14b are solder, a brazing material, or metal sintered compacts. The solder used is lead-free solder. The lead-free solder contains, as a major component, an alloy containing at least two selected from tin, silver, copper, zinc, antimony, indium, and bismuth, for example. Further, the solder may include an additive, such as nickel, germanium, cobalt, or silicon. The inclusion of the additive increases wettability, brightness, and bond strength of the solder, which results in improved reliability. The brazing material contains, as a major component, at least one selected from an aluminum alloy, a titanium alloy, a magnesium alloy, a zirconium alloy, and a silicon alloy, for example. The isolated circuit board 11 may be bonded to the cooling device 3 by brazing using such bonding members. The metal sintered compacts contain, for example, silver or a silver alloy as a major component. Alternatively, the bonding members may be a thermal interface material. The thermal interface material is an adhesive material including, for example, an elastomer sheet, room temperature vulcanization (RTV) rubber, gel, and a phase change material. The installation of the cooling device 3 via the foregoing brazing material or thermal interface material improves heat dissipation of the semiconductor units 10.

The semiconductor chip 12 includes a power device element made of silicone. The power device element may be a reverse-conducting insulated gate bipolar transistor (RC-IGBT). The RC-IGBT has integrated functions of both an IGBT, which is a switching element, and a free-wheeling diode (FWD), which is a diode element.

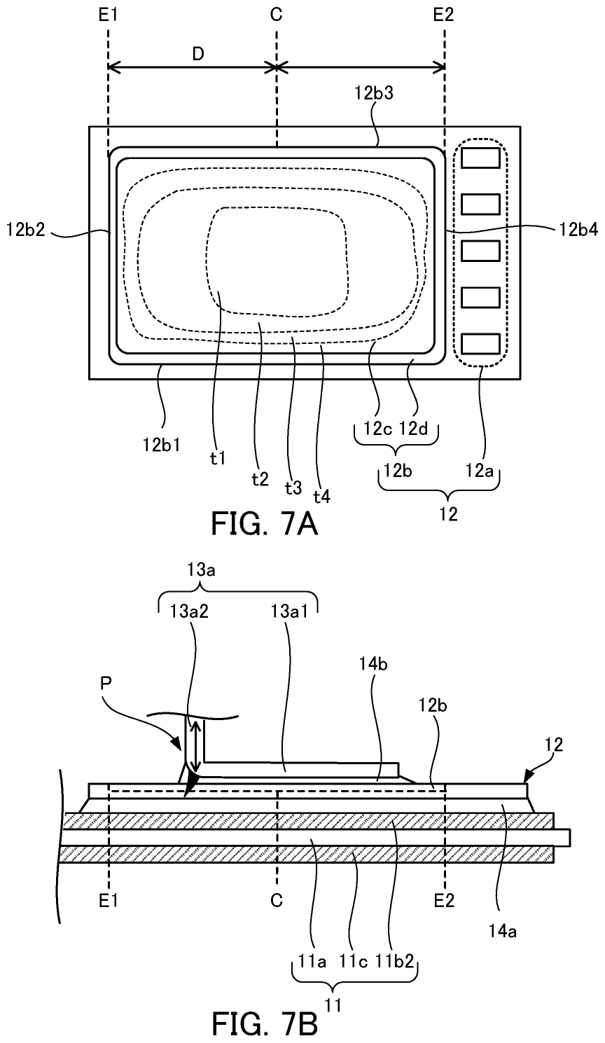

The front surface of each aforementioned semiconductor chip 12 has a rectangular shape in plan view, and includes control electrodes 12a (a gate electrode) and an output electrode 12b (a source electrode functioning as a main electrode), which is an upper electrode (see also FIG. 7A). The case depicted in FIGS. 5 and 6 is where the control electrodes 12a are formed on the short side of the front surface of the semiconductor chip 12.

The multiple control electrodes 12a are laid out in a row, close to and along a first short side of the front surface of the semiconductor chip 12. A control signal is input to the control electrodes 12a. The output electrode 12b has a rectangular shape in plan view. Note that the front surface of the output electrode 12b is surrounded on all four sides by electrode lateral surfaces 12b1, 12b2, 12b3, and 12b4 in plan view, as described with reference to FIG. 7A. The electrode lateral surface 12b1 may correspond to a first lateral surface. In the output electrode 12b, the electrode lateral surfaces 12b1 and 12b3 correspond to the long sides, and the electrode lateral surfaces 12b2 and 12b4 correspond to the short sides. The positions of the electrode lateral surfaces 12b2 and 12b4 in the longitudinal direction are denoted by positions E1 and E2, respectively.

The output electrode 12b is provided close to a second short side of the front surface of the semiconductor chip 12, adjacent to the control electrodes 12a. When the center of the output electrode 12b is defined as a center C, the center C is located in the middle of the electrode lateral surfaces 12b2 and 12b4 (the positions E1 and E2). The shortest distance from the center C to the position E1 (the electrode lateral surface 12b2) is, for example, distance D. Similarly, the shortest distance from the center C to the position E2 (the electrode lateral surface 12b4) is also the distance D.

The output electrode 12b further includes an electrode region 12c and a wiring structure part 12d. The electrode region 12c is a region at which current is output from the semiconductor chip 12. A plating layer may be formed in the electrode region 12c, and the electrode region 12c may include a gate runner. The wiring structure part 12d is provided on the top face of the output electrode 12b in such a manner as to continuously surround the outer periphery of the electrode region 12c. In addition, an input electrode (a collector electrode functioning as a main electrode), whose reference numeral is not given, is provided on the rear surface of the semiconductor chip 12.

Note that, as the semiconductor chip 12, a pair of a switching element and a diode element may be used instead of an RC-IGBT. The switching element is, for example, an IGBT or power metal oxide semiconductor field effect transistor (power MOSFET). The semiconductor chip 12 including the switching element has, on its front surface, control electrodes (a gate electrode) and an output electrode (a source or emitter electrode functioning as a main electrode), and has, on its rear surface, an input electrode (a drain or collector electrode functioning as a main electrode). On the other hand, the semiconductor chip 12 including the diode element may use, for example, a Schottky barrier diode (SBD) or a P-intrinsic-N (PiN) diode as an FWD. This semiconductor chip 12 has, on its front surface, an input electrode (an anode electrode functioning as a main electrode), and has, on its rear surface, an output electrode (a cathode electrode functioning as a main electrode).

Alternatively, instead of an RC-IGBT, the semiconductor chip 12 may use a power MOSFET made of silicone carbide. The body diode of the power MOSFET may perform similar functions to the FWD of the RC-IGBT. This semiconductor chip 12 has, on its front surface, control electrodes (a gate electrode) and an output electrode (a source electrode functioning as a main electrode), and has, on its rear surface, an input electrode (a drain electrode functioning as a main electrode).

The rear surface of each semiconductor chip 12 is bonded onto the predetermined wiring board 11b2 or 11b1 via the bonding member 14a. The bonding member 14a is solder or a metal sintered compact. The solder used is lead-free solder. The lead-free solder contains, as a major component, an alloy containing at least two selected from tin, silver, copper, zinc, antimony, indium, and bismuth, for example. Further, the solder may include an additive, such as nickel, germanium, cobalt, or silicon. The inclusion of the additive increases wettability, brightness, and bond strength of the solder, which results in improved reliability. The metal used for the metal sintered compact is, for example, silver or a silver alloy.

The lead frames 13a and 13b electrically connect the semiconductor chips 12 and the wiring boards 11b2 and 11b3, to make wiring connections. The semiconductor unit 10 may be a device that serves as a single-phase inverter circuit. The lead frame 13a directly connects the output electrode 12b of the semiconductor chip 12 (on the wiring board 11b2) and the wiring board 11b3. The lead frame 13b connects the output electrode 12b of the semiconductor chip 12 (on the wiring board 11b1) and the wiring board 11b2.

The lead frame 13a includes a main electrode bonding part 13a1, a first rising part 13a2, a linking part 13a3, a second rising part 13a4, and a wiring bonding part 13a5. Note that the lead frame 13a has a flat plate-like shape, and is mainly made of a metal as described later. The lead frame 13a has a thickness in the range of 0.45 mm to 0.55 mm, inclusive, for example, 0.5 mm. The thickness of the lead frame 13a is substantially uniform throughout. Within the lead frame 13a, at least the first rising part 13a2, the linking part 13a3, and the second rising part 13a4 may have a substantially uniform width in the ±X direction. The width of the wiring bonding part 13a5 in the ±X direction may be the same or larger than that of the first rising part 13a2, the linking part 13a3, and the second rising part 13a4 in the same direction.

The front surface of the main electrode bonding part 13a1 has a rectangular shape in plan view, and is surrounded sequentially by terminal lateral surfaces on all four sides. The four terminal lateral surfaces include a terminal lateral surface (second lateral surface) P corresponding to the short side of the main electrode bonding part 13a1. The main electrode bonding part 13a1 is bonded to the output electrode 12b via the bonding member 14b, with the terminal lateral surface P facing a chip lateral surface (third lateral surface), which is the short side of the semiconductor chip 12.

Furthermore, the terminal lateral surface P of the main electrode bonding part 13a1 is separated from the center C of the output electrode 12b toward the electrode lateral surface 12b2 by 40% or more of the length of the distance D. For example, when the length between the electrode lateral surfaces 12b2 and 12b4 (the positions E1 and E2, respectively) of the output electrode 12b is about 20 mm, the distance D is about 10 mm. Therefore, the terminal lateral surface P of the main electrode bonding part 13a1 is separated from the center C of the output electrode 12b by 4 mm or more toward the electrode lateral surface 12b2. In addition, the terminal lateral surface P of the main electrode bonding part 13a1 may be located on the inner side (the center C side) relative to the wiring structure part 12d of the output electrode 12b.

The first rising part 13a2 is integrally joined to the terminal lateral surface P of the main electrode bonding part 13a1, and extends upward relative to the main electrode bonding part 13a1 from the terminal lateral surface P. According to the first embodiment, the first rising part 13a2 is substantially orthogonal to the main electrode bonding part 13a1. The first rising part 13a2 has a predetermined height (in the ±Z direction). The outer side of the connection portion (corner) of the first rising part 13a2 to the main electrode bonding part 13a1 is separated by a predetermined distance L from the chip lateral surface of the semiconductor chip 12, located on the electrode lateral surface 12b2 side. The distance L is, for example, in the range of 1.0 mm to 1.5 mm, inclusive. This allows a creepage distance needed for the dielectric withstanding voltage between the lead frame 13a and the semiconductor chip 12 to be maintained.

The linking part 13a3 is integrally connected to an upper end of the first rising part 13a2 in the +Z-direction. The linking part 13a3 runs parallel to the front surface of the isolated circuit board 11 and extends (in the −Y direction) to the wiring board 11b3 in plan view.

The second rising part 13a4 is integrally connected to one end of the linking part 13a3, closer to the wiring board 11b3 (in the −Y direction), and extends to the wiring board 11b3 (in the −Z direction). The wiring bonding part 13a5 has, for example, a rectangular shape in plan view and is joined to the wiring board 11b3. One end of the wiring bonding part 13a5, closer to the wiring board 11b2, and one end of the linking part 13a3, closer to the wiring board 11b3 (in the −Y direction), are integrally connected by the second rising part 13a4. At this time, the second rising part 13a4 is substantially orthogonal to the wiring bonding part 13a5.

Although detailed explanation is not given here, the lead frame 13b may also include a main electrode bonding part, a first rising part, a linking part, a second rising part, and a wiring bonding part, as with the lead frame 13a. Similarly to the lead frame 13a, the lead frame 13b has a terminal lateral surface of the main electrode bonding part, separated from the center C of the output electrode 12b toward the electrode lateral surface 12b2 (the position E1) by 40% or more of the length of the distance D. Also, in the lead frame 13b, the first rising part is connected to the terminal lateral surface P of the main electrode bonding part, located closer to the short side of the output electrode 12b. The linking part of the lead frame 13b extends from the first rising part to the wiring board 11b2 in plan view.

The above-described semiconductor units 10 are housed in the unit housing parts 21e, 21f, and 21g. Inner ends of the first connection terminals 22, extending into the unit housing parts 21e, 21f, and 21g, are directly connected to the wiring boards 11b1. Inner ends of the second connection terminals 23, extending into the unit housing parts 21e, 21f, and 21g, are directly connected to the wiring boards 11b3. Inner ends of the output terminals 24, extending into the unit housing parts 21e, 21f, and 21g, are directly connected to the wiring boards 11b2. Note that the first connection terminals 22, the second connection terminals 23, and the output terminals 24 may be bonded to the wiring boards 11b1, 11b3, and 11b2 using the bonding members described above. Alternatively, the first connection terminals 22, the second connection terminals 23, and the output terminals 24 may be directly joined to the wiring boards 11b1, 11b3, and 11b2, for example, by laser or ultrasonic welding. In addition, the control electrodes 12a of the semiconductor chips 12 housed in the unit housing parts 21e, 21f, and 21g are directly connected to the control terminals 25a, 25b, and 25c by wires 26. The wires 26 may be made of, for example, aluminum, aluminum alloy, copper, or copper alloy.

The above-described lead frames 13a and 13b are made of a metal with excellent electrical conductivity. The metal is, for example, copper, aluminum, or an alloy including at least one of these. In order to provide improved corrosion resistance, plating may be applied to coat the surfaces of the lead frames 13a and 13b. In this case, a material used for plating is, for example, nickel, a nickel-phosphorus alloy, or a nickel-boron alloy. The plated lead frames 13a and 13b exhibit improved corrosion resistance.

The lead frames 13a and 13b may be joined to the wiring boards 11b3 and 11b2, respectively, by the bonding members (not illustrated) described above. The bonding members may be the aforementioned solder or sintered compacts. Alternatively, the lead frames 13a and 13b may be directly joined to the wiring boards 11b3 and 11b2, for example, by laser or ultrasonic welding. The lead frames 13a and 13b are joined to the output electrodes 12b of the semiconductor chips 12 via the bonding members 14b. The bonding members 14b are made of the same material as the bonding members 14a.

Next described is a case where the terminal lateral surface P of the main electrode bonding part 13a1 of the lead frame 13a is located closer to the center C of the output electrode 12b of the semiconductor chip 12 than in the first embodiment, with reference to FIGS. 7A and 7B. FIGS. 7A and 7B illustrate bonding of a lead frame to a semiconductor chip according to a reference example. Note that FIG. 7A depicts temperature distribution of the front surface of the output electrode 12b of the semiconductor chip 12. FIG. 7B is a cross-sectional view for the case where the terminal lateral surface P of the main electrode bonding part 13a1 of the lead frame 13a is located closer to the center C of the output electrode 12b of the semiconductor chip 12 than in the first embodiment.

First described is the temperature distribution of the front surface of the output electrode 12b of the semiconductor chip 12 during operation. The semiconductor chip 12 outputs an output current from the output electrode 12b. At this time, the output electrode 12b generates heat. FIG. 7A illustrates the temperature distribution of the front surface of the output electrode 12b generating heat, by connecting points having the same temperature with a dashed line. Here, a region with a temperature t1 has the highest temperature, and the temperature decreases in the order of regions with temperatures t2, t3, and t4. That is, the front surface of the output electrode 12b of the semiconductor chip 12 has the highest temperature near the center C. It may be seen that the temperature of the front surface of the output electrode 12b of the semiconductor chip 12 decreases from the center C toward the wiring structure part 12d (i.e., from the center C toward the outer periphery of the output electrode 12b).

Next described is the lead frame 13a positioned on the above-described output electrode 12b of the semiconductor chip 12. At this time, the terminal lateral surface P of the main electrode bonding part 13a1 of the lead frame 13a is located near the center C of the output electrode 12b of the semiconductor chip 12. The first rising part 13a2 rises substantially perpendicular to the main electrode bonding part 13a1. Therefore, the first rising part 13a2 of the lead frame 13a is heated and thereby extends in the vertical direction.

In addition, the terminal lateral surface P of the main electrode bonding part 13a1 of the lead frame 13a is located, for example, within the region with the temperature t1 of the output electrode 12b. Because the terminal lateral surface P of the main electrode bonding part 13a1 of the lead frame 13a is located in the highest temperature region of the output electrode 12b, the amount of extension of the first rising part 13a2 also increases. This may cause a crack in the bonding member 14b directly below the first rising part 13a2 (the terminal lateral surface P), and in some cases, the output electrode 12b directly below the bonding member 14b may also be damaged.

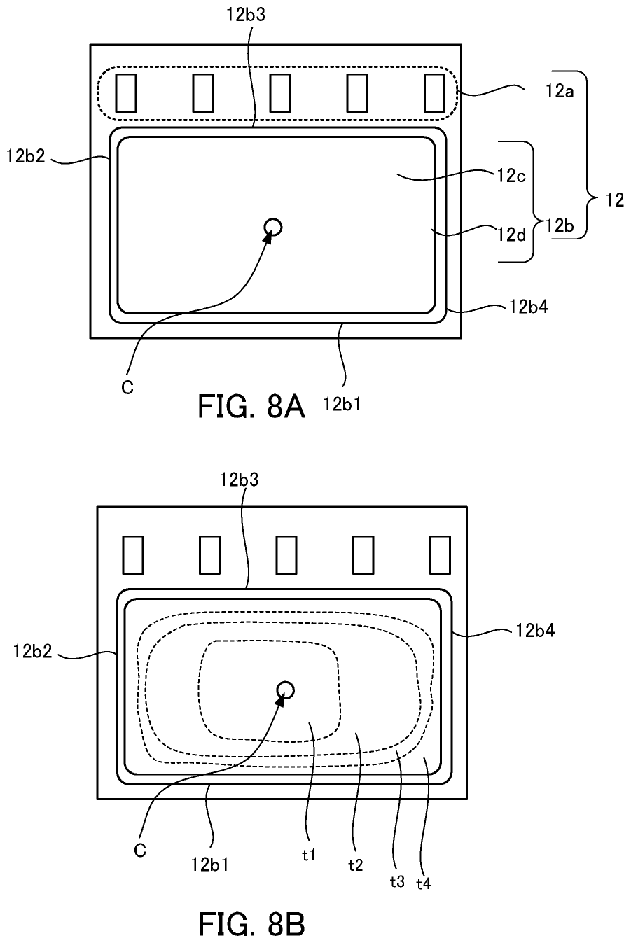

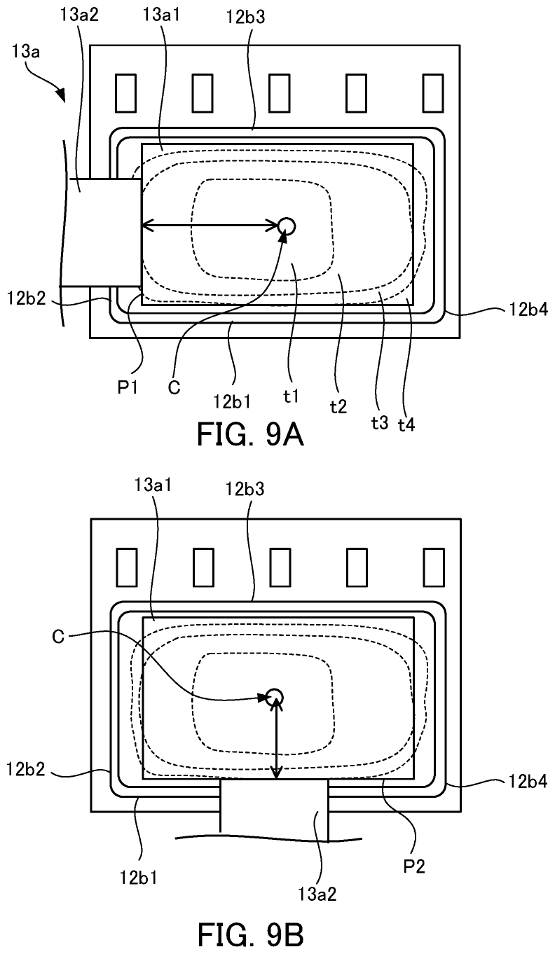

Next described is a case where a different semiconductor chip is used in the first embodiment, with reference to FIGS. 8 and 9. FIGS. 8A and 8B illustrate an output electrode of the different semiconductor chip included in the semiconductor device of the first embodiment. FIGS. 9A and 9B each illustrate a lead frame joined to the different semiconductor chip included in the semiconductor device of the first embodiment. Note that FIG. 8A is a plan view of the different semiconductor chip 12, and FIG. 8B depicts temperature distribution of the front surface of the output electrode 12b of the different semiconductor chip 12. FIGS. 9A and 9B each depict the lead frame 13a (the main electrode bonding part 13a1) in which the first rising part 13a2 is joined to a different place.

The front surface of the semiconductor chip 12 depicted in FIGS. 8A and 8B also has a rectangular shape in plan view, and includes the aforementioned control electrodes 12a and output electrode 12b. However, what is different here is that the control electrodes 12a are aligned close to the long side of the front surface of the semiconductor chip 12.

The multiple control electrodes 12a are laid out in a row, close to and along a first long side of the front surface of the semiconductor chip 12. The output electrode 12b has a rectangular shape in plan view, and the front surface thereof is surrounded on all four sides by the individual electrode lateral surfaces 12b1, 12b2, 12b3, and 12b4. In the output electrode 12b, the electrode lateral surfaces 12b1 and 12b3 correspond to the long sides, and the electrode lateral surfaces 12b2 and 12b4 correspond to the short sides. The output electrode 12b is provided close to a second long side of the front surface of the semiconductor chip 12, adjacent to the control electrodes 12a. When the center of the output electrode 12b is defined as the center C, the center C is located in the middle of the electrode lateral surfaces 12b1 and 12b3, and also located in the middle of the electrode lateral surfaces 12b2 and 12b4.

The output electrode 12b includes the electrode region 12c and the wiring structure part 12d on the front surface, and includes an input electrode (not illustrated) on the rear surface, as in the case of FIGS. 7A and 7B. When the semiconductor chip 12 depicted in FIGS. 8A and 8B outputs an output current from the output electrode 12b, the output electrode 12b also generates heat. Also, on the front surface of the output electrode 12b of the semiconductor chip 12 as illustrated in FIG. 8B, the temperature decreases in the order of the regions with the temperatures t1, t2, t3, and t4 from the center C toward the wiring structure part 12d.

Therefore, a terminal lateral surface of the main electrode bonding part 13a1 of the lead frame 13a, to which the first rising part 13a2 is connected, needs to be as far away from the center C of the output electrode 12b as possible. The terminal lateral surface to which the first rising part 13a2 is connected is located on the short or long side of the main electrode bonding part 13a1 of the lead frame 13a. Note that FIGS. 9A and 9B illustrate a case where the first rising part 13a2 is connected to a terminal lateral surface P1 (FIG. 9A) of the main electrode bonding part 13a1 and a case where the first rising part 13a2 is connected to a terminal lateral surface P2 (FIG. 9B) of the main electrode bonding part 13a1. The width of the first rising part 13a2 of the lead frame 13a, parallel to the terminal lateral surface P, is narrower than that of the terminal lateral surface P.

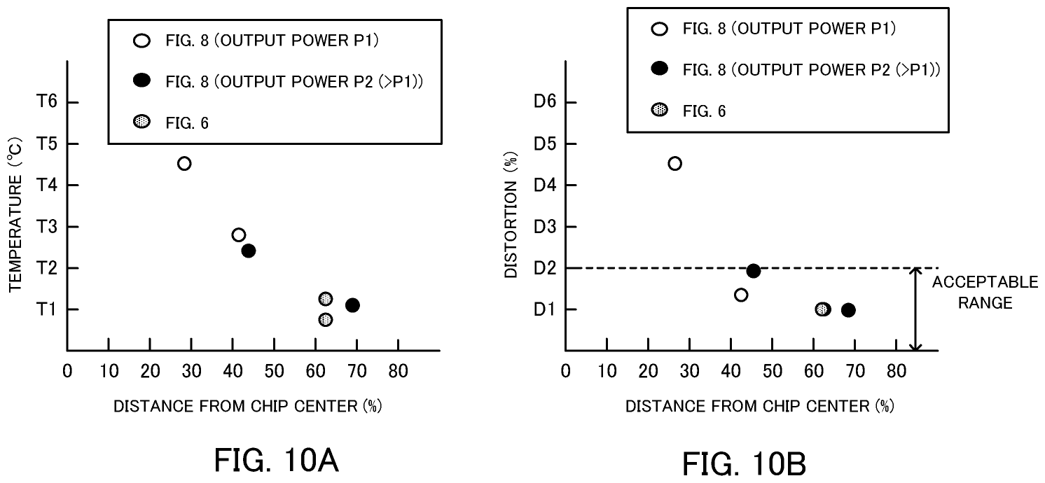

Next described are the temperature and distortion depending on the distance of the terminal lateral surface P (where the first rising part 13a2 is connected) of the main electrode bonding part 13a1 of the lead frame 13a from the center C of the front surface of the output electrode 12b of the semiconductor chip 12 in the cases of FIG. 6 and FIGS. 8A and 8B, with reference to FIGS. 10A and 10B. FIGS. 10A and 10B are graphs illustrating the temperature and distortion, respectively, in relation to the distance from the center of the output electrode of the different semiconductor chip included in the semiconductor device of the first embodiment.

Note that FIG. 10A is a graph representing the temperature of the output electrode 12b according to the distance of the terminal lateral surface P (where the first rising part 13a2 is connected) of the main electrode bonding part 13a1 of the lead frame 13a from the center C of the output electrode 12b of the semiconductor chip 12. The horizontal axis represents the ratio (%) to the distance from the center C of the output electrode 12b of the semiconductor chip 12 to an electrode lateral surface at the shortest distance. The vertical axis represents the temperature of the front surface of the output electrode 12b, at a position corresponding to the distance ratio. Note that six classes T1 to T6 are provided for the temperature where the temperature T1 is a reference and the temperature increases by 5° C. for each increment from the temperature T1 to the temperature T6.

On the other hand, FIG. 10B is a graph representing the distortion of the output electrode 12b depending on the distance of the terminal lateral surface P (where the first rising part 13a2 is connected) of the main electrode bonding part 13a1 of the lead frame 13a from the center C of the output electrode 12b of the semiconductor chip 12. The horizontal axis represents the ratio (%) to the distance as in FIG. 10A, and the vertical axis represents the distortion (%) in the front surface of the output electrode 12b, at a position corresponding to the distance ratio. Note that six classes D1 to D6 are provided for the distortion where the distortion D1 is a reference and the distortion increases by 0.02% for each increment from the distortion D1 to the distortion D6.

Regarding the legends of the graphs in FIGS. 10A and 10B, each white circle (o) represents the case where the output power of the semiconductor chip 12 of FIGS. 8A and 8B is an output power P1, and each black circle (.) represents the case where the output power of the semiconductor chip 12 of FIGS. 8A and 8B is an output power P2, which is larger than the output power P1. The remaining legend represents the case where the semiconductor chip 12 of FIG. 6 is used.

It may be seen, from FIG. 10A, that the temperature generally decreases as the distance from the center C of the output electrode 12b of the semiconductor chip 12 increases. According to FIG. 10B, in all cases, the distortion decreases as the distance from the center C of the output electrode 12b of the semiconductor chip 12 increases. This is considered to be due to a reduction in the amount of extension of the first rising part 13a2 with decreasing temperature, which in turn leads to reduced distortion in the output electrode 12b located directly below the first rising part 13a2 (the terminal lateral surface P of the main electrode bonding part 13a1). In view of the results presented in FIGS. 10A and 10B, it may be seen that the temperature and distortion are sufficiently reduced when the ratio to the distance from the center C of the output electrode 12b of the semiconductor chip 12 is 40% or more.

The above-described semiconductor device 1 includes the semiconductor chips 12, the lead frames 13a, and the bonding members 14b. Each of the semiconductor chips 12 has, on its front surface, the output electrode 12b, which has the electrode lateral surface 12b2 included in the electrode lateral surfaces 12b1, 12b2, 12b3, and 12b4 surrounding the outer periphery of the output electrode 12b in plan view. The electrode lateral surface 12b2 is separated by the shortest distance D from the center of the output electrode 12b. Each of the lead frames 13a includes the main electrode bonding part 13a1 and the first rising part 13a2. The main electrode bonding part 13a1 has the terminal lateral surface P, which is included in the terminal lateral surfaces surrounding the outer periphery in plan view, and is joined to the output electrode 12b such that the terminal lateral surface P faces the electrode lateral surface 12b2. The first rising part 13a2 is formed on the terminal lateral surface P of the main electrode bonding part 13a1 and extends upward relative to the output electrode 12b from the terminal lateral surface P. Each of the bonding members 14b joins the output electrode 12b and the main electrode bonding part 13a1. At this time, the terminal lateral surface P on which the first rising part 13a2 is formed is separated from the center C of the output electrode 12b toward the electrode lateral surface 12b2 by 40% or more of the distance D. Therefore, the terminal lateral surface P with the first rising part 13a2 formed thereon is subject to reduced impact of heat from the output electrode 12b of the heated semiconductor chip 12, which in turn reduces extension of the first rising part 13a2. As a result, the stress on the bonding member 14b directly below the first rising part 13a2 (the terminal lateral surface P of the main electrode bonding part 13a1) and the output electrode 12b of the semiconductor chip 12 is reduced, which thereby reduces the chance of damage to the bonding member 14b and the output electrode 12b of the semiconductor chip 12. This contributes to improved reliability of the semiconductor device 1.

### (b) Second Embodiment

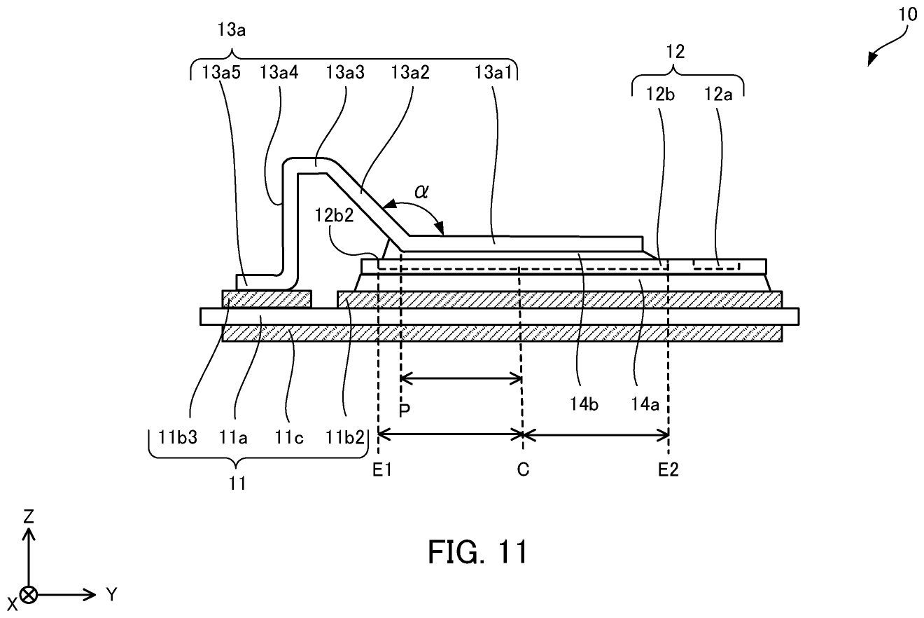

A semiconductor device of a second embodiment has the same configuration as the semiconductor device 1 of the first embodiment although no illustration is given here. However, the semiconductor device of the second embodiment differs in the lead frames 13a and 13b included in the semiconductor unit 10. The semiconductor unit 10 of the second embodiment is described below with reference to FIG. 11. FIG. 11 is a cross-sectional view of the semiconductor unit included in the semiconductor device of the second embodiment. Note that the cross-sectional view of FIG. 11 corresponds to that taken along dashed-dotted line X-X of FIG. 5.

In the lead frame 13a of the semiconductor unit 10 of FIG. 11, the first rising part 13a2 extends at an angle to the main electrode bonding part 13a1. Note that the inclination angle is denoted by a.

As described above, the first rising part 13a2 connected to the terminal lateral surface P of the main electrode bonding part 13a1 of the lead frame 13a is heated by the heat generating output electrode 12b of the semiconductor chip 12, and thereby extends. According to the second embodiment, because the first rising part 13a2 is tilted, the direction of extension of the first rising part 13a2 is also tilted to the output electrode 12b. For this reason, the applied stress is resolved into +Y direction and −Z direction components with respect to the terminal lateral surface P of the main electrode bonding part 13a1. At this time, the −Z direction stress is applied to the bonding member 14b and the output electrode 12b directly below the first rising part 13a2 (the terminal lateral surface P). Therefore, the first rising part 13a2 being tilted reduces the stress applied to the output electrode 12b (in the −Z direction).

In order to reduce the stress caused to the output electrode 12b due to the extension of the first rising part 13a2, it is desirable that the angle α be larger. However, if the angle α is too large, the overall length of the lead frame 13a in the ±Y direction becomes long, which leads to increased size of the semiconductor device 1. In addition, when the angle α is too large, the first rising part 13a2 may come close to the chip lateral surface of the semiconductor chip 12 on the electrode lateral surface 12b2 side. As described in the first embodiment, the first rising part 13a2 needs to be separated by the distance L from the chip lateral surface of the semiconductor chip 12 on the electrode lateral surface 12b2 side. Therefore, the angle α may be in the range of, for example, 130° to 140°, inclusive, so that the overall length of the lead frame 13a in the ±Y direction does not increase and the creepage distance is secured.

Only the portion of the first rising part 13a2, connected to the main electrode bonding part 13a1, may be inclined. That is, the first rising part 13a2 connecting the main electrode bonding part 13a1 and the linking part 13a3 does not necessarily need to have a flat, plate-like shape. For example, the first rising part 13a2 may be tilted by, for example, 140° or more to the main electrode bonding part 13a1 and then bend in the middle to extend to the linking part 13a3.

In the above-described second embodiment, the terminal lateral surface P on which the first rising part 13a2 is formed is separated from the center C of the output electrode 12b toward the electrode lateral surface 12b2 by 40% or more of the distance D. As a result, the terminal lateral surface P with the first rising part 13a2 formed thereon is less affected by heat from the heated output electrode 12b of the semiconductor chip 12, which in turn reduces the extension of the first rising part 13a2. This reduces the stress on the bonding member 14b directly below the first rising part 13a2 (the terminal lateral surface P of the main electrode bonding part 13a1) and the output electrode 12b of the semiconductor chip 12. Furthermore, the tilted first rising part 13a2 reduces the stress applied to the output electrode 12b, which further reduces the chance of damage to the bonding member 14b and the output electrode 12b of the semiconductor chip 12, compared to the first embodiment. This contributes to improved reliability of the semiconductor device 1.

### (c) Third Embodiment

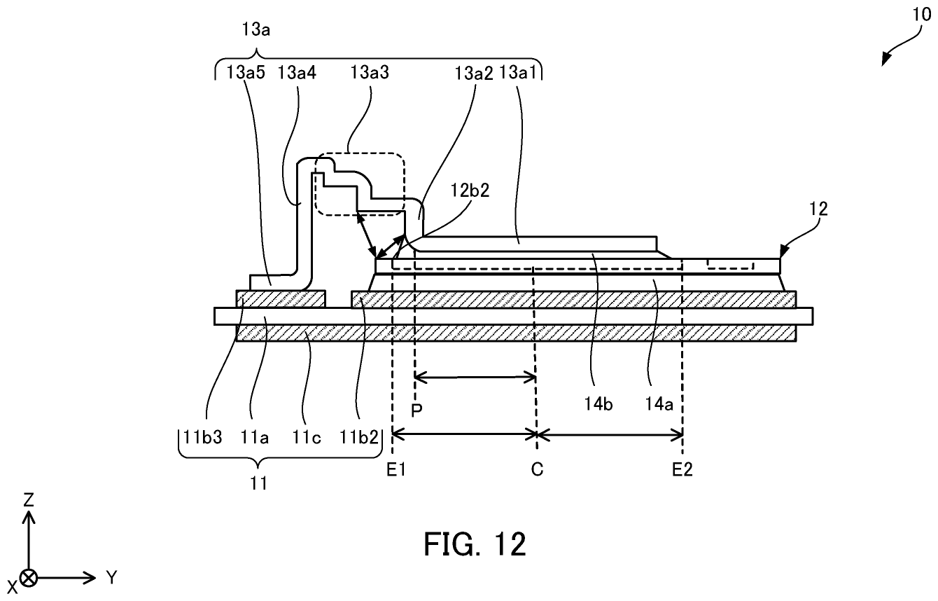

A semiconductor device of a third embodiment also has the same configuration as the semiconductor device 1 of the first embodiment although no illustration is given here. However, the semiconductor device of the third embodiment differs in the lead frames 13a and 13b included in the semiconductor unit 10. The semiconductor unit 10 of the third embodiment is described below with reference to FIG. 12. FIG. 12 is a cross-sectional view of the semiconductor unit included in the semiconductor device of the third embodiment. Note that the cross-sectional view of FIG. 12 corresponds to that taken along dashed-dotted line X-X of FIG. 5.

In the lead frame 13a of the semiconductor unit 10 of FIG. 12, the first rising part 13a2 is shorter in height than the first rising part 13a2 of FIG. 6. The linking part 13a3 connecting the upper end of the foregoing first rising part 13a2 and the upper end of the second rising part 13a4 has a stepped shape.

As described above, the first rising part 13a2 connected to the terminal lateral surface P of the main electrode bonding part 13a1 of the lead frame 13a is heated by the heat generating output electrode 12b of the semiconductor chip 12, and thereby extends. According to the third embodiment, the first rising part 13a2 has a lower height and a reduced volume than in the case of FIG. 6. The decreased volume of the first rising part 13a2 results in a reduction in the amount of extension due to heating. The reduced amount of extension of the heated first rising part 13a2 leads to reduced stress applied to the output electrode 12b.

Because having steps formed thereon, the linking part 13a3 may come close to the chip lateral surface of the semiconductor chip 12 on the electrode lateral surface 12b2 side. As described in the first embodiment, the first rising part 13a2 and the linking part 13a3 need to be separated by the distance L from the chip lateral surface of the semiconductor chip 12 on the electrode lateral surface 12b2 side. As long as the first rising part 13a2 has a height that maintains the distance L from the chip lateral surface of the semiconductor chip 12 on the electrode lateral surface 12b2 side, it is desirable that the height of the first rising part 13a2 is as low as possible.

In addition, the linking part 13a3 may connect the first rising part 13a2 and the second rising part 13a4 while maintaining the distance L from the chip lateral surface of the semiconductor chip 12 on the electrode lateral surface 12b2 side. The steps of the linking part 13a3 depicted in FIG. 12 are just an example, and the number and height of the steps are not limited to this case. Furthermore, the linking part 13a3 does not necessarily have a stepped shape. For example, the linking part 13a3 may connect the upper end of the first rising part 13a2 and that of the second rising part 13a4 so as to form a flat surface.

In the above-described third embodiment, the terminal lateral surface P on which the first rising part 13a2 is formed is separated from the center C of the output electrode 12b toward the electrode lateral surface 12b2 by 40% or more of the distance D. As a result, the terminal lateral surface P with the first rising part 13a2 formed thereon is less affected by heat from the heated output electrode 12b of the semiconductor chip 12, which in turn reduces the extension of the first rising part 13a2. This reduces the stress on the bonding member 14b directly below the first rising part 13a2 (the terminal lateral surface P of the main electrode bonding part 13a1) and the output electrode 12b of the semiconductor chip 12. Furthermore, the first rising part 13a2 configured to be short in height reduces the stress applied to the output electrode 12b, which further reduces the chance of damage to the bonding member 14b and the output electrode 12b of the semiconductor chip 12, compared to the first embodiment. This contributes to improved reliability of the semiconductor device 1.

Note that the second and third embodiments above describe the cases where the techniques of these embodiments are applied to the first embodiment. However, the techniques of the second and third embodiments are applicable to cases where the terminal lateral surface P with the first rising part 13a2 formed thereon is not separated from the center C of the output electrode 12b toward the electrode lateral surface 12b2 by 40% or more of the distance D. Even in such cases, the stress applied to the output electrode 12b is reduced, which in turn improves the reliability of the semiconductor device 1.

According to the disclosed techniques, damage to the main electrode of the semiconductor chip caused by the lead frame connected to the main electrode is reduced, which contributes to improved reliability of the semiconductor device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip including at a chip front surface thereof, an upper electrode having an electrode front surface and electrode lateral surfaces that surround an outer periphery of the upper electrode in a plan view of the semiconductor device, the electrode lateral surfaces including a first lateral surface;
a lead frame having a bonding part and a rising part, the bonding part having a bonding front surface and terminal lateral surfaces that surround an outer periphery of the bonding part in the plan view, the terminal lateral surfaces including a second lateral surface, the bonding part being joined to the electrode front surface of the upper electrode such that the second lateral surface faces the first lateral surface, the rising part extending upward with respect to the electrode front surface from the second lateral surface; and
a bonding member joining the upper electrode to the bonding part, wherein
in a direction parallel to the electrode front surface, a first shortest distance between a center of the electrode front surface in the plan view and the second lateral surface is equal to or greater than 40% of a second shortest distance between the first lateral surface and the second lateral surface.

2. The semiconductor device according to claim 1, wherein 40% of the second shortest distance is 4 mm.

3. The semiconductor device according to claim 1, wherein:
the electrode front surface of the upper electrode has short sides and long sides forming a rectangular shape, the first lateral surface being at one of the short sides of the electrode front surface, and
the bonding front surface of the bonding part of the lead frame has short sides and long sides forming a rectangular shape, the second lateral surface being at one of the short sides of the bonding front surface.

4. The semiconductor device according to claim 1, wherein
the semiconductor chip has chip lateral surfaces that surround an outer periphery of the semiconductor chip in the plan view, the chip lateral surfaces including a third lateral surface that faces the first lateral surface, and
the rising part of the lead frame extends upward with respect to the electrode front surface from the second lateral surface, an outer surface of the rising part being apart from the third lateral surface by a distance equal to or greater than an insulation distance that is needed for a dielectric withstanding voltage of the semiconductor chip.

5. The semiconductor device according to claim 1, wherein the rising part of the lead frame has a stepped shape in a side view of the semiconductor device so as to extend upward with respect to the electrode front surface from the second lateral surface of the bonding part of the lead frame.

6. The semiconductor device according to claim 1, wherein the rising part of the lead frame is inclined with respect to the bonding front surface.

7. The semiconductor device according to claim 6, wherein an angle formed by the rising part and the bonding part is in a range of 130 degrees to 140 degrees, inclusive.

8. The semiconductor device according to claim 1, further comprising a wiring structure part disposed at an outer periphery of the semiconductor chip, wherein
in the plan view, the second lateral surface of the bonding part of the lead frame is located closer to the center of the electrode front surface than is the wiring structure part.

9. The semiconductor device according to claim 8, wherein, in the plan view, the bonding part is disposed on the semiconductor chip inside an area where the wiring structure part is disposed.

10. The semiconductor device according to claim 1, wherein, in a direction parallel to the second lateral surface, a width of the rising part of the lead frame is narrower than a width of the second lateral surface.

11. The semiconductor device according to claim 1, wherein the bonding part of the lead frame has four corners that are R-chamfered in the plan view.

12. A semiconductor device, comprising:
a semiconductor chip including at a front surface thereof, an upper electrode having chip lateral surfaces that surround an outer periphery of the upper electrode in a plan view of the semiconductor device, the chip lateral surfaces including a first lateral surface;
a lead frame including a bonding part and a rising part, the bonding part having terminal lateral surfaces that surround an outer periphery of the bonding part in the plan view, the terminal lateral surfaces including a second lateral surface, the bonding part being joined to the upper electrode such that the first lateral surface faces the second lateral surface, the rising part extending upward with respect to the electrode front surface from the first lateral surface; and
a bonding member joining the upper electrode to the bonding part, wherein:
the rising part has a stepped shape in a side view of the semiconductor device so as to extend upward with respect to the electrode front surface from the second lateral surface.
